(19) United States
(12) Patent Application Publication
(10) Pub. No.: US 2012/0160170 A1
(43) Pub. Date: Jun. 28, 2012

(54) VAPOR PHASE GROWTH APPARATUS

(75) Inventors: Akira Yamaguchi, Tokyo (JP); Koh Matsumoto, Tokyo (JP); Kosuke Uchiyama, Tokyo (JP)

(73) Assignee: TAIYO NIPPON SANSO CORPORATION, Tokyo (JP)

(21) Appl. No.: 13/383,876

(22) PCT Filed: Jul. 12, 2010
(86) PCT No.: PCT/JP2010/061767

§ 371 Date: Mar. 14, 2012

(30) Foreign Application Priority Data
Jul. 15, 2009 (JP) 2009-166831

(51) Int. Cl. C23C 16/455

(52) U.S. Cl. 118/725

(57) ABSTRACT

Disclosed is a rotation/revolution type vapor phase growth apparatus that can maintain constant flow rates of a purge gas and a raw material gas when a raw material gas introducing direction is set to be the same as a susceptor rotation introducing direction. Inside a hollow drive shaft 12 supporting and rotating a disk-shaped susceptor 13, a raw material gas supply tube 20 is coaxially disposed, and between the hollow drive shaft and the raw material gas supply tube, a purge gas flow path 21 is formed. Additionally, in a purge gas introducing nozzle introducing a purge gas in an outer circumferential direction of a flow channel 18 from the purge gas flow path, a gas introducing path 19c is formed in a direction parallel to an upper surface of the susceptor in such a manner as to make a vertical dimension of the gas introducing path constant.

### TECHNICAL FIELD

The present invention relates to a vapor phase growth apparatus, and particularly to a rotation/revolution type vapor phase growth apparatus that performs vapor phase growth of a thin film, particularly of a nitride-based compound semiconductor thin film on a substrate surface while rotating/revolving the substrate.

### BACKGROUND ART

As a vapor phase growth apparatus performing vapor phase growth on multiple substrates at a time, there is known a rotation/revolution type vapor phase growth apparatus in which a plurality of rotation susceptors are arranged in a circumferential direction of an outer periphery of a revolution susceptor, and a bearing and an external gear are provided at an outer periphery of each of the rotation susceptors to mesh a fixed internal gear provided inside a reactor vessel (chamber) and the external gear with each other, thereby rotating/revolving the substrate during film deposition (for example, see Patent Literature 1). Additionally, as an apparatus performing vapor phase growth while rotating susceptors, there is known a silicon epitaxial apparatus in which a raw material gas introducing direction is set to be the same as a susceptor rotation introducing direction (for example, see Patent Literature 2).

### PRIOR ART REFERENCES

### Patent Literatures

Patent Literature 1: JP-A-2007-266121

Patent Literature 2: JP-U-1974-000140

### SUMMARY OF THE INVENTION

### Problems to be Solved by the Invention

Regarding raw materials gas used in production of recent nitride-based compound semiconductor thin films, for example, mixing together both organic metal and ammonia that are highly reactive facilitates generation of particles. Accordingly, an organic metal gas and an ammonia gas as raw material need to be mixed together upon introduction of them into a reactor (a vapor phase growth chamber). On the other hand, in a structure described in Patent Literature 2, when a raw material gas is radially introduced, only a raw material gas ejected from a hole near a substrate surface contributes to the growth of a film, whereas a raw material gas ejected from a hole above the hole does not contribute to the film growth, resulting in a waste of the raw material gas.

Additionally, as described in Patent Literature 2, when rotation introduction and gas introduction are set to be in the same direction, it is inevitable to employ a double tube structure in which a gas introducing tube is inserted into a hollow rotation shaft of a rotation holder. However, when such a double tube structure is employed, a purge gas needs to be flown all the time to prevent impurities from entering a vapor phase growth chamber from a space between an inner circumferential surface of the rotation shaft and an outer circumferential surface of a the gas introducing tube or prevent a raw material gas from leaking out conversely from the vapor phase growth chamber to the outside.

However, it is extremely difficult to accurately and coaxially dispose and maintain the rotation shaft to be rotated and the gas introducing tube to be fixed. If coaxiality of both of them is lost, a cross-sectional area of the space is circumferentially different. Thus, a flow rate of the purge gas flowing into the vapor phase growth chamber becomes different in the circumferential direction of the vapor phase growth chamber.

In this respect, in a conventional silicon epitaxial apparatus as described in Patent Literature 2, a slight difference in flow rate of the purge gas hardly matters. However, for example, in the case of vapor phase growth of the above-mentioned nitride-based compound semiconductor thin film, a slight flow-rate difference of the purge gas has significant influence on film deposition. Furthermore, when a plurality of raw material gases are mixed together upon introduction of the gases into a vapor phase growth chamber, a flow rate of each raw material gas needs to be maintained at a constant level upon the introduction of the gases into the vapor phase growth chamber.

Accordingly, it is an object of the present invention to provide a rotation/revolution type vapor phase growth apparatus that can maintain constant flow rates of a purge gas and a raw material gas when a raw material gas introducing direction is set to be the same as a susceptor rotation introducing direction.

### Means for Solving the Problems

To achieve the above object, a vapor phase growth apparatus according to the present invention includes a disk-shaped susceptor supported by a hollow drive shaft to be rotatably provided inside a chamber; a plurality of external gear members, each external gear member being provided rotatably in a circumferential direction of an outer periphery of the susceptor; a ring-shaped fixed internal gear member having an internal gear meshing with the each external gear member; a heating unit for heating each substrate retained by the each external gear member; a flow channel for introducing a raw material gas in a direction parallel to a surface of the substrate; a nozzle for introducing the gas in an outer circumferential direction from a center portion of the flow channel; and a raw material gas supply tube for supplying the raw material gas to the nozzle, the raw material gas supply tube being disposed coaxially inside the hollow drive shaft, in which a purge gas flow path for flowing a purge gas in a direction of the flow channel is formed between an inner circumferential surface of the hollow drive shaft and the raw material gas supply tube, and a purge gas introducing nozzle for introducing the purge gas in the outer circumferential direction of the flow channel from the purge gas flow path is formed in a direction parallel to an upper surface of the susceptor in such a manner as to make a vertical dimension of the nozzle constant.

Additionally, in the vapor phase growth apparatus according to the present invention, the nozzle is projectingly provided in a disk shape by being bent in the outer circumferential direction of the flow channel from an upper end of the raw material gas supply tube; a vertical dimension of a gas flow path at a tip portion of the raw material gas nozzle is made smaller than a vertical dimension of a gas flow path on a base portion side of the raw material gas nozzle; and the nozzle tip portion with the smaller vertical dimension has a length no less than 1.5 times the vertical dimension of the gas flow path on the base portion side of the nozzle.

### Advantages of the Invention

In the vapor phase growth apparatus according to the present invention, the purge gas introducing nozzle is projected in the disk shape inside the flow channel in the direction parallel to the upper surface of the susceptor. Accordingly, even if axial displacement occurs between the hollow drive shaft and the raw material gas supply tube and thereby the flow rate of the purge gas flowing through the purge gas flow path becomes uneven in the circumferential direction, the flow rate can be corrected to an even flow rate in a susceptor circumferential direction in a region of the purge gas introducing nozzle to be introduced into the flow channel In addition, reducing the vertical dimension of the tip portion of the raw material gas introducing nozzle can equalize a flow rate of the raw material gas introduced into the flow channel from the raw material gas supply tube via the raw material gas introducing nozzle.

### BRIEF DESCRIPTION OF THE DRAWINGS

FIG. 1 shows a cross-sectional front view showing an embodiment example of a vapor phase growth apparatus according to the present invention.

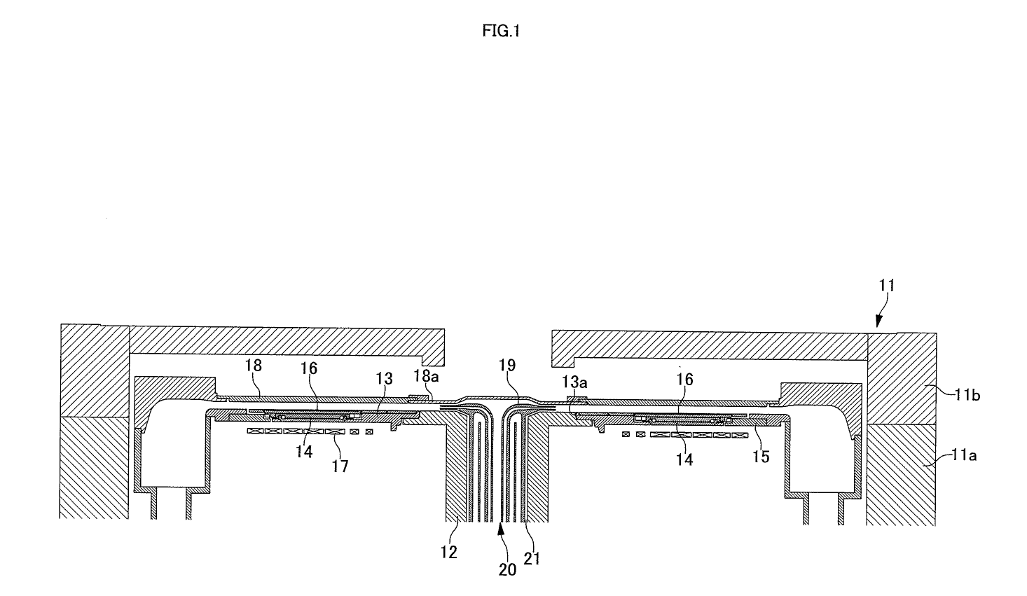

FIG. 2 shows a cross-sectional front view of a main part of the embodiment example thereof

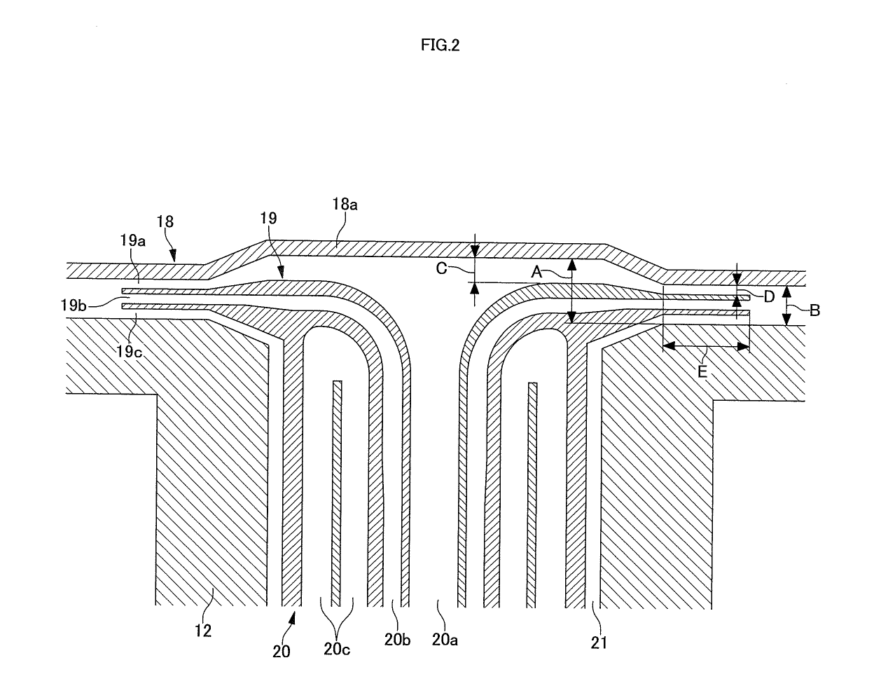

### MODES FOR CARRYING OUT THE INVENTION

In a vapor phase growth apparatus shown in the present embodiment example, inside a chamber 11 are disposed a disk-shaped susceptor 13 provided rotatably by supporting a circular opening 13a formed at a center portion by an upper end of a hollow drive shaft 12, a plurality of external gear members (rotation susceptors) 14, each external gear member being provided rotatably in a circumferential direction of an outer periphery of the susceptor 13, a ring-shaped fixed internal gear member 15 having an internal gear meshing with the each external gear member 14, a heating unit 17 for heating each substrate 16 retained on an upper surface of the each external gear member 14, a flow channel 18 for introducing a raw material gas in a direction parallel to a surface of the substrate 16, a nozzle 19 for introducing a raw material gas or a purge gas in an outer circumferential direction from a center portion of the flow channel 18, and a raw material gas supply tube 20 for supplying the raw material gas to the nozzle 19.

The chamber 11 is composed of a lower fixed member 11a and an upper ascent/descent member 11b provided ascendably/descendably with respect to the lower fixed member 11a, and also, a top plate 18a of the flow channel 18 is formed movably upward. Additionally, the fixed internal gear member 15 is formed movably downward. When the substrate 16 on which film deposition has been completed is replaced by a new substrate 16, the entire part of the susceptor 13 including the external gear member 14 retaining the substrate 16 is taken out from the chamber 11 for the replacement in a condition in which the upper ascent/decent member 11b of the chamber 11 and the top plate 18a of the flow channel 18 have been ascended while the fixed internal gear member 15 has been descended.

The raw material gas supply tube 20 is disposed coaxially inside the hollow drive shaft 12, and a purge gas flow path 21 is formed between an inner circumferential surface of the hollow drive shaft 12 and an outer circumferential surface of the raw material gas supply tube 20. The raw material gas supply tube 20 shown in the present embodiment example has a multiple tube structure. A first raw material gas is supplied to a center flow path 20a and a second raw material gas is supplied to an intermediate flow path 20b. A temperature adjusting fluid is flown through an outer circumferential flow path 20c.

The nozzle 19 has upper to lower triple gas introducing paths 19a, 19b, and 19c projected in a disk shape by being bent in an outer circumferential direction of the flow channel 18 from an upper end of the raw material gas supply tube 20. The upper gas introducing path 19a is a first raw material gas introducing nozzle for introducing a first raw material gas supplied from the center flow path 20a of the raw material gas supply tube 20 into the flow channel 18. The middle gas introducing path 19b is a second raw material gas introducing nozzle for introducing a second raw material gas supplied from the intermediate flow path 20b of the raw material gas supply tube 20 into the flow channel 18. The lower gas introducing path 19c is a purge gas introducing nozzle for introducing a purge gas from the purge gas flow path 21 into the flow channel 18.

At a center portion of the flow channel 18 where a base portion of the nozzle 19 is disposed, the top plate 18a is offset upwardly. A vertical dimension A of the center portion of the flow channel 18 is made larger than a vertical dimension B of a main body portion (the portion except for the center portion) of the flow channel 18 where the substrate 16 is disposed. Additionally, in the upper gas introducing path 19a of the nozzle 19, a vertical dimension D of a tip side of the gas introducing path 19a is made smaller than a vertical dimension C of a base portion side of the gas introducing path 19a, as well as a length E of the portion where the vertical dimension

D of the nozzle tip side is made smaller is formed to be no less than 1.5 times the vertical dimension C of the base portion side of the gas introducing path 19a. Forming the gas introducing path 19a as described above allows for a smooth flow of the first raw material gas flowing from the center of the nozzle in a radially extended manner to be supplied in a substrate direction from the tip of the nozzle. Thereby, the raw material gas can be supplied evenly to each substrate surface.

The length E can be arbitrarily determined according to a distance from the nozzle tip to the substrate 16. However, when the nozzle tip is heated to high temperature by radiant heat from the substrate 16 and the main body portion of the flow channel 18 that are put in a high temperature condition by the heating unit 17, the raw material gas may be decomposed. In addition, when the nozzle tip is too close to the substrate 16, respective gases flown out from the tip of the nozzle 19 are not sufficiently mixed together and reach an upper surface of the substrate 16, which may disturb the formation of a thin film. Therefore, according to conditions such as the vertical dimension B of the flow channel 18, a diameter of the susceptor 13 and a diameter of the circular opening 13a, a diameter of the substrate 16 and the number of processed substrates 16, and the like, the length E can be determined to be no less than 1.5 times the vertical dimension C.

Meanwhile, the lower gas introducing path 19c of the nozzle 19 is formed in a direction parallel to the upper surface of the susceptor 13 in such a manner as to make the vertical dimension of the gas introducing path 19c constant, and the tip of the path 19c is set to be at the same position as that of each nozzle tip of each of the gas introducing paths 19a and 19b. Accordingly, the first raw material gas, the second raw material gas, and the purge gas become a three-layered stream from the tip of the nozzle 19 to be introduced into the flow channel 18, and near the substrate 16, the respective gases are appropriately mixed together to form a stream, which reaches the upper surface of the substrate 16, whereby a predetermined reaction proceeds to form a predetermined thin film on the substrate surface.

In that case, if the raw material gas supply tube 20 and the hollow drive shaft 12 are in an eccentric condition, a circumferential cross-sectional area of the purge gas flow path 21 changes, so that the flow rate of the purge gas reaching the nozzle 19 becomes different in the circumferential direction. Thus, for example, as described in Patent Literature 1 above, when gas is merely introduced into the center of the flow channel, the gas flow rate and gas flow speed are different in the circumferential direction of the flow channel. This has influence on the growing speed of a thin film formed on the substrate surface, which may disturb an equalized formation of a thin film.

On the contrary, as described above, by forming the gas introducing path 19c of the nozzle 19 in the direction parallel to the upper surface of the susceptor 13 in such a manner as to make the vertical dimension of the gas introducing path 19c constant, the flow rate and flow speed of the purge gas in the circumferential direction can be equalized by a flow path resistance of the gas introducing path 19c, thereby allowing the purge gas to evenly flow in the substrate direction. This can equalize the mixing of the purge gas with the raw material gas and can average the growing speed of a thin film formed on the substrate surface, resulting in the formation of an even thin film

As described above, the flow rates of the purge gas and the raw material gas can be maintained constant and can be evenly mixed together in a predetermined condition to be supplied to the substrate portions. This allows for the efficient and stable production of a nitride-based compound semiconductor thin film, which uses a highly reactive raw material gas, for example, raw material gases of an organic metal and ammonia. This can prevent a waste of raw material gas and can also contribute to the reduction of production cost.

Additionally, the middle gas introducing path 19b and the lower gas introducing path 19c can be formed to have the same structure as that of the upper gas introducing path 19a. Furthermore, the raw material gas may be of one kind or three or more kinds.

### DESCRIPTION OF REFERENCE NUMERALS

11 . . . Chamber

11a . . . Lower fixed member

11b . . . Upper ascent/descent member

12 . . . Hollow drive shaft

13 . . . Susceptor

13a . . . Circular opening

14 . . . External gear member (rotation susceptor)

15 . . . Fixed internal gear member

16 . . . Substrate

17 . . . Heating unit

18 . . . Flow channel

18a . . . Top plate

19 . . . Nozzle

19a . . . Upper raw material gas introducing path

19b . . . Middle gas introducing path

19c . . . Lower gas introducing path

20 . . . Raw material gas supply tube

20a . . . Center flow path

20b . . . Intermediate flow path

20c . . . Outer circumferential flow path

21 . . . Purge gas flow path

1. A vapor phase growth apparatus comprising a disk-shaped susceptor supported by a hollow drive shaft to be rotatably provided inside a chamber; a plurality of external gear members, each external gear member being provided rotatably in a circumferential direction of an outer periphery of the susceptor; a ring-shaped fixed internal gear member having an internal gear meshing with the each external gear member; a heating unit for heating each substrate retained by the each external gear member; a flow channel for introducing a raw material gas in a direction parallel to a surface of the substrate; a nozzle for introducing the gas in an outer circumferential direction from a center portion of the flow channel; and a raw material gas supply tube for supplying the raw material gas to the nozzle, the raw material gas supply tube being disposed coaxially inside the hollow drive shaft, wherein a purge gas flow path for flowing a purge gas in a direction of the flow channel is formed between an inner circumferential surface of the hollow drive shaft and the raw material gas supply tube, and a purge gas introducing nozzle for introducing the purge gas in the outer circumferential direction of the flow channel from the purge gas flow path is formed in a direction parallel to an upper surface of the susceptor in such a manner as to make a vertical dimension of the nozzle constant.

2. The vapor phase growth apparatus according to claim 1, wherein the nozzle is projectingly provided in a disk shape by being bent in the outer circumferential direction of the flow channel from an upper end of the raw material gas supply tube; a vertical dimension of a gas flow path at a tip portion of the raw material gas nozzle is made smaller than a vertical dimension of a gas flow path on a base portion side of the raw material gas nozzle; and the nozzle tip portion with the smaller vertical dimension has a length no less than 1.5 times the vertical dimension of the gas flow path on the base portion side of the nozzle.
